(19) United States
(12) Patent Application Publication
(10) Pub. No.: US 2014/0262453 A1
(43) Pub. Date: Sep. 18, 2014

(54) Transparent conductive electrodes and their structure design, and method of making the same

(71) Applicant: NUOVO FILM, INC., Jiangsu (CN)

(72) Inventor: Hakfei Poon, Mountain View, CA (US)

(73) Assignee: NUOVO FILM, INC., Jiangsu (CN)

(21) Appl. No.: 14/213,872

(22) Filed: Mar. 14, 2014

Related U.S. Application Data
(60) Provisional application No. 61/802,497, filed on Mar. 16, 2013.
(60) Provisional application No. 61/803,206, filed on Mar. 19, 2013.

(51) Int. Cl. H05K 1/02; H05K 3/38; H05K 3/12

(52) U.S. Cl. CPC H05K 1/0274; H05K 3/12; H05K 3/381; H05K 3/386
USPC 174/253; 427/108

(57) ABSTRACT

A transparent conductive electrode comprising a single transparent conductive layer comprising a network of nanowires of different diameters and a diffused conductive material wrapping around the nanowires is disclosed. The transparent conductive electrode has a thickness of 200 nm or less, and exhibits >90% transparency in wavelength between 400-1000 nm and tunable sheet resistance from 0.1 Ohm/sq-1000 Ohm/sq.

### TECHNICAL FIELD OF THE DISCLOSURE

This present patent application relates, in general, to the art of transparent electrodes, including their structures and method of making, and more particularly, to the art of fabricating transparent electrodes on large area substrates in a high throughput low cost manufacturing process for electro-optical applications.

### BACKGROUND OF THE DISCLOSURE

Indium tin-oxide (ITO) is traditionally widely used as a transparent conductor in transparent electrodes in science and research community, but it also has well drawbacks in large scale manufacturing processes. First, in order to make electrodes, ITO is vacuum deposited onto substrates, and the vacuum deposition process is expensive and low throughput. Second, in most of applications, 150 nm or thicker of ITO is needed to ensure electrical performance, but at such thicknesses, ITO films become brittle making them not feasible for applications requiring large areas or flexible substrates. Third, to achieve good conductivity and clarity, ITO films need to be annealed at high temperatures, preferably over 200 C, thus limiting its application on high temperature resistant substrates such as glass. Due to the low softening point of polymers, most polymer based ITO films cannot withstand the annealing temperatures required for achieving the high conductivity and transparency at the same time. Therefore as electro-optical applications expand to more novel and exotic functionalities, such as 3-dimensional displays and solar cells, there is an increasing demand to invent alternative transparent electrodes with better than or comparable optical and electrical performance of ITO but suitable for large area flexible substrate and can be manufactured in an inexpensive high through manner.

Alternative transparent electrodes have been explored and demonstrated in the art as ITO replacements, including other transparent conductive oxides, thin metal films, carbon nanotubes (CNTs), metal nanowires, and graphene.

### SUMMARY

The present invention discloses a transparent conductive electrode that not only can be manufactured at low cost and on a large scale but with excellent performance including conductivity and transparency.

In one embodiment, a transparent conductive electrode is disclosed herein. The transparent electrode is a substantially single layer structure comprising a hierarchical architecture, comprised of nanowires of the same or different diameters, and has a thinner than usual thickness. The said electrode is substantially transparent in 400-1000 nm and has extremely low haze, and conductivity of the said electrode can tuned in the range of 0.1 Ohm/square to 1000 Ohm/square.

In another embodiment, a method of making a transparent electrode is disclosed herein, the method comprising preparing an ink solution containing a first group of nanowires and a second group of nanowires; functionalizing the substrate on the surface where the growth of the first group of nanowires occur; depositing the nanowire ink onto the surface of the substrate; and curing the resultant film to let the first group of nanowires interact specifically with the surface of the substrate to form the skeleton of a nanowire network and land the second group of nanowires in between the first group of nanowires.

In yet another embodiment, an alternative method of making a transparent electrode is disclosed herein, the method comprising: preparing a first ink solution having nanowire at a first diameter; preparing a second ink solution having nanowire at a second diameter; and depositing the first and second ink solutions onto the substrate sequentially to form a nanowire network.

In another aspect of the present invention, a transparent electrode with improved adhesion is disclosed. The transparent conductive electrode having improved adhesion in the present invention, comprises a substrate, and a single layer of conductive material deposited on top of the substrate. The single layer conductive material comprises one or more metal nanowires. In one embodiment of the present invention, The single layer conductive material comprises adhesion promoters allows the interface between the substrate and conductive material layer disappear after an annealing step.

In another embodiment of the present invention, the transparent electrode with improved adhesion in the present invention comprises a substantially a single layer structure, comprising a zone substantially of a substrate, and another zone having more metal nanowires than the zone of substrate. The transparent conductive electrodes with improved adhesion disclosed herein have an optical transmittance higher than 90%, a haze value less than 2%, while maintaining the sheet resistance lower than 100 Ohms/sq.

In still another embodiment of the present invention, a method of making of the electrode with improved adhesion is disclosed. The method comprises a deposition step, laying down a mixture comprising nanowires and a thermoplastic polymer on top of the substrate, and a drying step forming a conductive film adhering to the substrate, and an annealing step, applying a temperature or pressure or both to remove the stress in the film, wherein the thermoplastic polymer is a semi-crystalline polymer when the substrate is a film made of a semi-crystalline polymer, and the thermoplastic polymer is a amorphous polymer when the substrate is a film made of a amorphous polymer.

In still another embodiment of the present invention, a method of making of the electrode with improved adhesion is disclosed. The method comprises a deposition step, laying down a mixture comprising nanowires and a polymer on top of the substrate, and a drying step forming a conductive film adhering to the substrate, and a annealing step, applying a temperature or pressure or both to remove the stress in the film, wherein the polymer has substantially the same composition as the substrate but differs in molecular weight.

In still another embodiment of the present invention, a method of making of the electrode with improved adhesion is disclosed. The method comprises a deposition step, laying down first a layer of polymer on top of the substrate, followed by a mixture comprising nanowires and with/without a polymer, and a drying step forming a conductive film adhering to the substrate, and an annealing step, applying a temperature or pressure or both to remove the stress in the film, wherein the polymer has substantially the same composition as the substrate but differs in molecular weight.

### BRIEF DESCRIPTION OF THE DRAWINGS

Exemplary embodiments of the disclosure will be more clearly understood from the following detailed description taken in conjunction with the accompanying drawings in which:

FIG. 1 diagrammatically illustrates a cross-section view of the two-layer hybrid electrode in the prior art;

FIG. 2 diagrammatically illustrates a cross-sectional view of a single layer transparent conductive electrode in the present invention;

FIG. 3 diagrammatically illustrates a top view of an exemplary top surface of the two-layer hybrid electrode in the prior art, with the rest of electrode layer structure included in the dotted line for explanation purpose;

FIG. 4 diagrammatically illustrates a top view of an exemplary top surface of a single layer transparent conductive electrode in the present invention, with the rest of electrode layer structure included in the dotted line for explanation purpose;

FIG. 5 is a prior art;

FIG. 6a-c is a detail anatomy illustration of one exemplary two-layer hybrid electrode in the prior art in FIG. 5, in view of the thickness requirement in the prior art, and FIG. 6a is a cross-section view, FIG. 6b is a top view of the top surface and FIG. 6c is a top view of the bottom surface;

FIG. 7a-c is a detail anatomy illustration of another exemplary two-layer hybrid electrode in the prior art in FIG. 5, in view of the thickness requirement in the prior art, and FIG. 7a is a cross-section view, FIG. 7a is a top view of the top surface and FIG. 7c is a top view of the bottom surface;

FIG. 8a-c is a detail anatomy illustration of still another exemplary two-layer hybrid electrode in the prior art in FIG. 5, in view of the thickness requirement in the prior art, and FIG. 8a is a cross-section view, FIG. 8b is a top view of the top surface and FIG. 8c is a top view of the bottom surface;

FIG. 9a-c is a detail anatomy illustration of another exemplary single layer hybrid electrode in the present invention, in view of the thickness requirement in accordance with the aspects of the present invention, and FIG. 9a is a cross-section view, FIG. 9b is a top view of the top surface and FIG. 9c is a top view of the bottom surface;

FIG. 10a-c is a detail anatomy illustration of another exemplary single layer hybrid electrode in the present invention, in view of the thickness requirement in accordance with the aspects of the present invention, and FIG. 10a is a cross-section view, FIG. 10b is a top view of the top surface and FIG. 10c is a top view of the bottom surface;

FIG. 11 is a detail anatomy illustration of still another exemplary single layer hybrid electrode in the present invention, in view of the thickness requirement in accordance with the aspects of the present invention, and FIG. 11 is a cross-section view;

FIG. 12 is a detail anatomy illustration of yet still another exemplary single layer hybrid electrode in the present invention, in view of the thickness requirement in accordance with the aspects of the present invention, and FIG. 12 is a cross-section view;

FIG. 13 is an illustration of one exemplary single layer hybrid electrode having the leaf design in accordance with the aspects of the present invention;

FIG. 14 is an illustration of an alternative exemplary single layer hybrid electrode having the leaf design with freely ending nanowire veins, in accordance with the aspects of the present invention;

FIG. 16 is an exemplary electrode having a substantial a single layer structure with two zones;

FIGS. 17a-c illustrate the method steps to form an exemplary electrode of FIG. 16;

FIG. 18 is an alternative exemplary electrode having a substantial a single layer structure with gradient zones; and

FIGS. 19a-d illustrate the method steps to form an exemplary electrode of FIG. 18.

### DETAILED DESCRIPTION OF SELECTED EXAMPLES

Hereinafter, selected examples of a transparent conductive electrode will be discussed with reference to the accompanying drawings. It will be appreciated by those skilled in the art that the following discussion is for demonstration purposes, and should not be interpreted as a limitation. Other variances within the scope of this disclosure are also applicable.

“Optional” or “optionally” means that the subsequently described circumstance may or may not occur, so that the description includes instances where the circumstance occurs and instances where it does not.

In the scope of the present invention, in some instances, “top” means situated at the highest position in a figure or a stack. “Top view” means what an observer sees looking down at the top. In some instances, bottom electrode means a device is built from it whereas a top electrode means an electrode situated on top of the device stack.

### Single Layer

In one embodiment of the present invention, the transparent conductive electrode (TCE) comprises a substrate and a single conductive layer, comprising nanowires and diffused conductive materials.

Referring to FIG. 1, an exemplary transparent conductive electrode (TCE) (100) in the prior art is diagrammatically illustrated. The transparent conductive electrode (TCE) (100) in this example comprises a metal nanowire network layer (104) and an isotropic conductive material layer (106). The end of the metal nanowires (108) in this cross-section view is included for clarification purposes. The nanowire network layer (104) is coated on the substrate 102 and the conductive material layer (106) is disposed on the nanowire network layer (104). In the transparent conductive electrode (TCE) (100), the more conductive metal nanowire network transports charges into the less conductive isotropic conductive material layer (106). In this prior art example, the nanowire layer (104) and isotropic conductive material layer (106) are two distinctive layers and most of the charge transfers from nanowire to the isotropic conductive material happen at the interface of the two layers, and the charge transport is limited because the contact between the metal nanowire network and isotropic conductive material is limited.

The present invention discloses an improved layer design of the transparent conductive electrode (200). FIG. 2 is a cross-section view of an exemplary transparent conductive electrode (200). As shown in FIG. 2, the transparent conductive electrode (200), in the present invention, comprises a metal nanowire network and isotropic conductive materials in substantially one layer, the transparent conductive layer (202). The ends of metal nanowires (108) are shown in this exemplary diagram for clarity purposes and should not be construed as a limitation, only the ends the metal nanowire are present in the conductive layer (202) or the cross-section view of the layer (202). In the single conductive layer (202), the network of highly conductive material, metal nanowires (108) are embedded in the less conductive materials (106, not labeled in the FIG. 2). Compared to prior art's bilayer structure (FIG. 1), wherein the metal nanowire network and isotropic conductive material are positioned separately in two different layers (104 and 106), the single layer (202) design in the present invention exhibits extraordinary performance in terms of both conductivity and optical transmittance. The embedded single conductive layer (202) provides enhanced electrical contact between the nanowires and the conductive materials and results in a more efficient electrical transmission (transportation) and distribution. In addition, the transparent conductive electrode (200) has more desired optical transmittance. Because intermixing between the metal nanowires and conductive materials leads to a refractive index change of the layer, which in turn changes the light propagation pathway in the electrode (200) in the 400-1000 nm ranges.

Further, FIG. 3 and FIG. 4 illustrate the top views of the transparent electrode in the prior art 100 (cross-section view in FIG. 1) and the transparent electrode in the present invention 200 (cross-section view in FIG. 2). The rest of the layer structures such as substrate (102), nanowire layer (104) are shown for the purpose of clarification. As the two top views in FIG. 3 and FIG. 4 demonstrate, the top surface of the prior art TCE (100) has only conductive material 106 whereas the top surface of the TCE (200) in the present invention, which is the surface of 202, has both the conductive material 106 (not labeled), ends of the nanowires (108) and sides or lengths of the nanowires (208). In view of the foregoing, the TCE of the present invention (200) is substantially different from the prior art TCE (100).

FIG. 2F and paragraph 64 in U.S. patent application Ser. No. 12/610,247 teaches a TCE with greater surface contact between the nanowires and the conductive material layer by using high viscosity solutions and obtaining a binderless TCE. FIG. 5 is the same FIG. 2F in U.S. patent application Ser. No. 12/610,247, wherein 102 is the substrate, 108 are nanowires and layer 502 is the conductive material layer deposited on the surfaces of the nanowires (108). U.S. patent application Ser. No. 12/610,247 teaches clearly the nanowires are deposited onto the substrate by a solution process step and the conductive material layers are over coated onto the nanowires in a different step. In accordance the aspects of U.S. patent application Ser. No. 12/610,247, in one instance, the TCE is as shown in FIG. 6a-c, wherein the nanowires 108 are laid down and surface of the substrate 102 and immobilized and conductive materials are subsequently deposited on to surface of the nanowires (108). By doing so, a layer of conductively material but not nanowires also forms. Referring FIG. 6a, the TCE 502 is consist of a substrate 102 and a hybrid material film 502, with a bottom layer having nanowires 108 and optionally conductive material 106 and a top layer with conductive material only. FIG. 6b shows the top view of top surface of the hybrid layer 502 and the TCE 600, wherein only conductive material 106 is present. FIG. 6c shows the top view of top surface of the hybrid layer 502, wherein both the different layout of the nanowires (108 and 208) and conductive materials (106) are present. FIG. 7a-c illustrate alternative instances using the techniques described in U.S. patent application Ser. No. 12/610,247, wherein the conductive material was first laid down and nanowires 108 are deposited, resulting a layer structure depicted in FIG. 7a. The TCE 600 in this instance, having a top surface (FIG. 7b) consisting of nanowires (108 and 208) and optionally conductive material 106 (not labeled), and a bottom surface next the substrate (FIG. 7c), having just conductive material 106. FIG. 8a-c diagrammatically illustrate still another instance of TCE 600 in accordance to the aspects of the invention in U.S. patent application Ser. No. 12/610,247, wherein the nanowires are situated in between the conductive material layers 106. In this instance, both the bottom is next to substrate and top surface of the conductive material 106 but not nanowires. In summary, in view of the relative thickness of the conductive material layers and nanowire layers, and sequential deposition steps taught by U.S. patent application Ser. No. 12/610,247, at least one of the two non-substrate surfaces of the TCE 600 has not nanowires.

FIGS. 9a-c, FIGS. 10a-c, FIG. 11, and FIG. 12 are various instances of the present invention, where the TCE 200 comprises a substrate 102 and a single layer conductive layer 202. Said conductive layer 202 comprises nanowires 108 and conductive materials 106. In some examples, the total thickness of 202 is 200 nm or less. In another example, the thickness of conductive materials is 100-200 nm or less. In a more preferred examples, the thickness of the conductive material is 20 to 30 nm or less. In one instance of the present invention, shown in FIGS. 9a-c, wherein a very thin layer film of the conductive material is first formed on the surface of the substrate 102, after which a solution of the nanowire solution is coated onto said conductive material film. The layer 202 comprises at least two zones (FIG. 9a), a first zone, closer to the substrate or bottom surface of 202, with preferentially more conductive materials whereas a second zone, closer to the top surface of 202, with preferentially more nanowires 108. Because the conductive material is very thin, both the top surface and the bottom surface have metal nanowires (FIG. 9b-c). In another instance of the present invention, referring to FIGS. 10a-c, a layer of nanowires (108) is first deposited onto the surface of the substrate 102 and forms a network structure serving as a skeleton of the conductive layer (202). Subsequently, a thin layer of conductive material diffuses into the skeleton of the metal nanowire network, as illustrated in FIG. 10a, the conductive layer 202 of this instance having at least two zones. A first zone, closer to the surface of the substrate, has preferentially more nanowires than a second zone, closer to the top of the surface of 202 or TCE 200. And the first zone, closer to the surface of the substrate, has measurably less conductive materials than the second zone, closer to the top of the surface of 202 or TCE 200. Because of the thickness of the conductive material with respect to the total thickness of 202, the top view of the second zone (FIG. 10b) shows the presence of both conductive materials and different lay out of the nanowires (108 and 208). And the top view of the second zone (FIG. 10c) shows the presence of the nanowires (108 and 208). Both the surfaces of conductive layer 202 show the presence of the nanowires. FIG. 11 shows another instance where the conductive layer has more than two zones, having a zone not contacting either of the surfaces of 202 and being rich in conductive material compositions. In this instance, both of the surfaces of conductive layer 202 have metal nanowires. FIG. 12 further demonstrates yet another instance where the thickness of the conductive layer, the thickness of conductive material and the thickness of the metal nanowires are all comparable with each other. In this instance, both surfaces of the conductive layer have nanowires.

In view of the foregoing, the present invention discloses a TCE having a single layer conductive layer with at least one surface having nanowires. The surface of the conductive layer includes the surface in direct contact with the substrate, being sometimes called the bottom surface, and the surface contacting the rest of the device structure, positioned on the top in the FIGs, being sometimes called the top surface. Whereas U.S. patent application Ser. No. 12/610,247 teaches TCEs with (combined) two layers having at least one surface have conductive material but not nanowires. The surfaces herein are referred to include the surface next to the substrate and the surface situated on the top of the highest layer in the stack.

### Leaf Design

In another embodiment of the present invention, the transparent conductive electrode, comprising: a substrate; a transparent conductive layer, comprising a network of metal nanowires having a first group of nanowire veins and a second group of nanowire veins, wherein the first and second group of nanowire veins can be substantially the same or different in diameters, wherein the first group of nanowire veins form the skeleton of the network and the second group of nanowire veins branch out from the first group of nanowire veins, join another nanowire vein to form a closed loop or a continuous branching system; and a diffused conductive material formed in contact with the metal nanowire network which wraps around and fills between the nanowire veins.

### Size of Nanowires

In one aspect of the present invention, in one example, the metal nanowires in the network have substantially the same vein sizes. In a more preferred example of the present invention, the metal nanowires in the network have more than more distinctively different vein sizes. Some have different diameters and some have different lengths.

### Leaf Design Component

In another aspect of the present invention, in one example, the metal nanowire veins in the network have nanowires with both ends connected to neighboring nanowire in network (FIG. 13), sometimes being referred to as branched nanowire veins. In another example, the metal nanowires in the network have nanowires with only one end connected to neighboring nanowire in the network and the other end extends into the conductive material (FIG. 14), sometimes being referred as free end nanowire veins.

### How the Components are Put Together

In another aspect of the present invention, in one example, the bigger sizes nanowire veins (“primary veins”) form the basic skeleton of the nanowire network, and provide structural integrity to the conductive layer 202 and physical strength of the network, whereas the smaller sized nanowire veins (“secondary veins or capillary veins”) diverge from the bigger nanowire veins to form a continuous branching system. In another example, a few nanowire veins interconnected with each other form a close loop. Branched or freely ending nanowires may all extend into or embed in the conductive material layer being wrapped around them. Branched nanowires may bend and join with the adjacent secondary vein to form a closed loop.

The network of nanowire veins brings in charge circulation, transportation, and distribution within the more conductive network and between the network and less conductive isotropic conductive materials. The distinctive size orders of the various metal nanowire veins optimize the utilization of the conductive network, with “primary veins” carrying major currents and secondary and/or capillary veins distributing or collecting smaller local currents, thus forming a highly effective electron transport system. Comparing to a conventional conductive networks made of carbon nanotubes, the present invention uses less nanowires but can achieve same conductivity. Reduce amount of the nanowires in the network afford less shadow loss and higher transmittance of the TCE.

### Transparency

With preferred thicknesses of layer 202 and amounts of metal nanowire required in the present invention, the TCE 200 provides excellent optical transparency. In one example, the TCE has at least >80% optical transmittance in the wavelength of 400-1000 nm. In a preferred example, the TCE has at least >90% optical transmittance in the wavelength range of 400-1000 nm. In a more preferred example, the TCE has at least >95% optical transmittance from wavelengths of 400-1000 nm.

The haze value of the TCE in the present invention are tunable from >10% to <0.6%, depending on the application. In one example of the present invention, the haze of the TCE is >10%. In another example of the present invention, the haze of the TCE is <0.6%. The super low haze comes from the single layer design having transparent metal oxide wrapping around the nanowires which in turn reduce the light scattering from the nanowires.

### Conductivity

The transparent conductive electrode in the present invention is invented for electrical-optical devices. The single conductive layer design and detailed architecture with nanowire veins at difference sizes and networks that are both diverging or branching with free end nanowire veins are devised to improve the three-dimensional surface contact between the metal nanowire veins, cylindrical structures, and a continuous isotropic conductive material such as a film of conductive or semi-conductive metal oxide(s), conductive polymers, carbon nanotubes and the like.

In one example of one embodiment, referring to FIG. 2, the TCE comprising the conductive layer 202, without the nanowires (108 and 208), has an electrical resistance of at least about 200 ohms per square or more. In another example, referring to FIG. 2, the TCE comprising the conductive layer 202, without the nanowires (108 and 208), has an electrical resistance of at least about 300 ohms per square or more. In still another example, referring to FIG. 2, the TCE comprising the conductive layer 202, without the nanowires (108 and 208), has an electrical resistance of at least about 500 ohms per square or more.

In another embodiment of the present invention, the metal nanowire network has a sheet resistance tunable from 0.1 Ohm/sq to 1000 Ohm/sq.

In another embodiment of the present invention, the transparent conductive electrode, comprising: a transparent conductive layer, comprising a network of metal nanowires and a diffused conductive material formed in contact with the metal nanowire network and the conductive material wraps around and fills between the nanowire veins. Said diffused conductive material forms an isotropic layer for gathering charge from the junctions of the nanowires and/or delivering charge to the junctions of the nanowires. The isotropic diffuse conductive film in the interstices of nanowires has sheet resistance from 10 Ohm/sq to 1000 Ohm/sq.

### Nanowire

### Chemical Composition

In the present invention, nanowires may be comprised of one or more materials selected from a variety of electrically conductive materials, any noble elements etc. Elements in the period table that can be used as the chemical composition for metal nanowires (108 or 208) include, but not limited to, copper (Cu), silver (Ag), gold (Au), aluminum (Al), nickel (Ni), lead (Pd), platinum (Pt) or combinations thereof. The metals that can be used in the nanowire network can further include a silver plated copper, a gold plated silver, or a gold plated copper. The nanowires may also be comprised of one or more materials, such as but not limited to, Zn, Mo, Cr, W, Ta, metallic alloys, or the like. In the present invention, some less preferred examples include nanowires comprising metal oxides.

In one example of the present invention, the metal nanowire network consists of only one chemical composition throughout. In another example of the present invention, the metal nanowire network consists of a mixture of chemical compositions. In one instance, said mixture of chemical compositions includes metals or metal oxides. In another instance, said mixture of chemical compositions includes chemical compounds with different electrical properties, such as electrical conductivity. In another instance, said mixture of chemical compositions includes chemical compounds with different optical properties, such as optical transparency or refractive index.

In one preferred example of the present invention, one composition of the nanowire is present in a gradient concentration in the conductive layer 202.

In one example of the present invention, the nanowire may further comprise an anticorrosion coating or anti-reflective coating.

### Shape or Geometry

In the aforementioned instances, examples or embodiments of the present invention disclosed herein, the nanowires are described as having at least an end (108) or a length (208). This description is used primarily for the ease of discussion; it should be understood that any geometric shapes such as rods of different aspect ratios, dog-bone shapes, round particles, oblong particles, single or multiple combinations of different geometric shapes, or other particle configurations capable of forming a metal network may be used herein.

### Size or Dimension

In some embodiments of the present invention, diameters of nanowires in the network range from 10 nm to 1 um. In some examples of the present invention, wherein the diameters of nanowires have more than one size ranges, wherein one group of nanowires have diameters from 100 nm to 500 nm. Optionally another group of nanowires have diameters from 30-100 nm. Optionally still another group of nanowires have diameters from 10-30 nm.

In one embodiment of the present inventions, the nanowires are from 20-30 microns in length. In one preferred embodiment, a range of the size distribution of nanowires is used to create a hierarchical design with branching nanowire veins and free end nanowire veins.

Different sizes of nanowires can be prepared in one precursor solution or multiple precursor solutions. The precursor solutions can be applied to the substrate in one simultaneous step or separate steps.

In a preferred embodiment of the present invention, there is no binder in the nanowire precursor solution, and/or no binder ends up in the metal nanowire network (108 and 208), nor in the conductive layer 202.

### Electrical and Optical Property

Optionally, the transparent electrode without nanowires has an electrical resistance of at least about 500 ohms per square or more. Optionally, the transparent top electrode without nanowires has an electrical resistance of at least about 300 ohms per square or more. Optionally, the transparent electrode with the nanowire network in accordance with the aspects of the present invention has a sheet resistance of 0.1 Ohm/sq-499 Ohm/sq.

Optionally, the transparent electrode without nanowires has a transmittance of over 99% over the wavelength range of 400 nm-1000 nm. Optionally the transparent electrode with the nanowire network in accordance with the aspects of the present invention has an optical transmittance of >99%. Optionally the transparent electrode without the nanowires has a haze of <0.5% over the wavelength range of 400 nm-1000 nm. Optionally the transparent electrode with the nanowire network in accordance with the aspects of the present invention has a haze <1.0%.

### Nanowires Network Layout

Optionally, a maximum distance from any location in the transparent electrode to a nearest nanowire in the network is in the range between 1 to 20 microns. Optionally, a maximum distance from any location in the transparent electrode to a nearest nanowire in the network is in the range between 1 to 10 microns. Optionally, a maximum distance from any location in the transparent top electrode to a nearest nanowire in the network is in the range between 2 to 5 microns. In a preferred embodiment of the present invention, the nanowire network is formed by a wet-coating process or a solution process. Said wet-coating process leads to randomly oriented nanowires.

### Pitch

In accordance of the aspects of the present invention, the metal nanowire network can be randomly pitched or regularly pitched, with pitch spacing that can be tuned from 1 um to 100 um, and preferably below 50 um, and more preferably below 10 um.

### Deposition Method of Nanowires

The network of nanowires 108 and 208 may be formed by a variety of deposition techniques. A nanowire ink or dispersion may be formed for solution deposition of the nanowires (108 and 208) onto a substrate.

In one embodiment, the nanowire precursor dispersion or ink is prepared in a substantially aqueous solution of about 99% wt or higher percent of water with a loading of nanowires between about 0.2 to 1% wt. Optionally, the nanowires loading may be in the range of about 0.25 to 0.75% wt. Optionally, the nanowires loading may be in the range of about 0.25 to 0.50% wt. Further surfactants, additives or viscosity modifiers, may be added to the precursor solution to make solution deposition or coating or dispensing step more friendly in a continuous process.

It has been demonstrated that anybody skilled in the art can synthesize silver and copper nanowires that are 25 nm in diameter in gram quantities and up to 5 (for silver) or 10 (for copper) microns in length. Furthermore, one or more connection techniques may be used to couple the nanowires in the network together. Some embodiments may use heat such as annealing while others use pressure such as through rollers to force the nanowires into contact.

In a preferred embodiment, a solution, ink or dispersion of nanowire precursors is applied to the substrate using a wet-coating process.

Examples of the wet-coating process for an ink or dispersion of nanowire precursors may include at least one method from the group comprising: solution coating, dip coating, spray coating, spin coating, doctor blade coating, contact printing, top feed reverse printing, bottom feed reverse printing, nozzle feed reverse printing, gravure printing, microgravure printing, reverse microgravure printing, comma direct printing, roller coating, slot die coating, meyerbar coating, lip direct coating, dual lip direct coating, capillary coating, ink jet printing, jet deposition, spray deposition, aerosol spray deposition, dip coating, web coating, microgravure web coating, or combinations thereof. These applications of nanowires are compatible with roll to roll high throughput technology, producing lower costs, better durability, better thermal stability, and higher efficiency devices. Of course, other non-solution based techniques may also be used.

### Transparent Conductive Layer

### Chemical Composition and Deposition Method

The transparent conductive layer 59 may be inorganic, e.g., a transparent conductive oxide (TCO) such as but not limited to indium tin oxide (ITO), fluorinated indium tin oxide, zinc oxide (ZnO), Mg—ZnO, Li2O—ZnO, Zr—Zno, aluminum doped zinc oxide (AZO), gallium doped zinc oxide (GZO), boron doped zinc oxide (BZO).

The transparent conductive material 106 may be inorganic, e.g., a transparent conductive oxide (TCO), such as but not limited to, indium tin oxide (ITO), fluorinated indium tin oxide (FTO), zinc oxide (ZnO) or aluminum doped zinc oxide, Mg—ZnO, Li2O—ZnO, Zr—Zno, aluminum doped zinc oxide (AZO), gallium doped zinc oxide (GZO), boron doped zinc oxide (BZO), or a related material, which can be deposited using any of a variety of means including but not limited to sputtering, evaporation, chemical bath deposition (CBD), electroplating, sol-gel based coating, spray coating, chemical vapor deposition (CVD), physical vapor deposition (PVD), atomic layer deposition (ALD), and the like. Alternatively, the transparent conductive material 106 may include a transparent conductive polymeric layer, e.g. a transparent layer of doped PEDOT (Poly-3,4-Ethylenedioxythiophene), nanowires or related structures, or other transparent organic materials, either homopolymer, copolymer, polymer blends or in combination, which can be deposited using spin, dip, or spray coating, and the like or using any of various vapor deposition techniques. Optionally, it should be understood combinations of inorganic and organic materials can also be used to form a conductive material layer. Thus, 106 may optionally be an organic (polymeric or a mixed polymeric-molecular) or a hybrid (organic-inorganic) material. Alternatively, the conductive material can be conductive carbon nanotubes.

### Properties

The conductive layer 202 of the present invention offers significant reduced light scattering and improved optical transparency. In one embodiment of the present invention, the thickness of 202 is about ¼ of wavelength of the light. In one example, the thickness of the conductive material is in the range of 100-200 nm. In another example, the thickness of the conductive material is in the range of 20-30 nm. In another embodiment of the present invention, the refractive index of the conductive material is between 1.3-1.8. In another embodiment of the present invention, the conductive material has a physical pattern capable of changing the light propagation pathway affording reduced light scattering and better optical transparency.

### Substrate

In one example of the present invention, the substrate is a rigid substrate. The rigid substrate is a glass. In some instances, the glass has refractive index of more than 1.5. In some instances, the glass has a refractive index of more than 1.7.

In another example of the present invention, the substrate is a flexible substrate comprising a polymer. Examples of such a polymer includes, but not limited to, a polyimides (PI), polyamides, polyetheretherketone (PEEK), Polyethersulfone (PES), polyetherimide (PEI), polyethylene naphtalate (PEN), Polyester (PET), polycarbonate (PC), cyclo olefin polymer (COP) or copolymer (COC), polymethylmethacrylate (PMMA), or related polymers, a metallized plastic, and/or combination of the above and/or similar materials.

In a more preferred example, the polymer substrate has barrier properties. In one instances, the substrate is a piece of barrier film having oxygen permeation rate less than 10⁻² g/m²/day. In another instance, the substrate is a piece of barrier film having moisture permeation rate less than 10⁻² g/m²/day. In still another instance, the substrate is a piece of barrier film having moisture permeation rate less than 10⁻⁶ g/m²/day.

In still another example, the substrate is a curved substrate.

In yet another example, the substrate has regular geometries. Such geometries include the geometries of cell phones, tablets, TVs, e-books, windows and solar cells. In yet another example, the substrate has irregular geometries, including stars, pyramids and spheres etc.

### Location of the Electrode in a Device

The transparent conductive electrode in the present invention is ultimately used in electrical optical device. Optical properties such as transparency and electrical properties like conductivity make the transparent conductive electrode in the present invention suitable for a wide range of the applications. In one example, the transparent electrode 200 is a top electrode in a device. In another example, the electrode is a bottom electrode of a device. In still another example, the electrode of claim 1 is an electrode is of a stacked device.

### Method

In order to achieve a nanowire network with more than one distinctive size ranges using a solution process, new methods are disclosed in the present invention.

### One Ink, One Step

In one embodiment, a single step process is used. A method of forming the conductive metal nanowire network comprising nanowires having more than one distinctive diameter, includes the steps of: a) preparing an ink solution containing a first group of nanowires at a first group of diameters and a second group of nanowires at a second group of diameters; b) functionalizing a substrate on the surface where the growth of the first group of nanowires occur; c) depositing the nanowire ink onto the surface of the substrate; and d) drying the resultant film to let the first group of nanowires interact specifically with the surface of the substrate to form the skeleton of a nanowire network and land the second group of nanowires in between the first group of nanowires.

The method comprises a step of: reacting the first group of nanowires specifically with the surface of the substrate and forming a chemical bond.

Optionally, the method further comprises a step of: formulating the ink solution in order to allow the second group nanowires to land in between the first of group nanowires.

### Two Solutions, Two Steps

In another embodiment of the present invention, the method of making a transparent electrode comprising nanowires having different diameters, comprises the steps of a) preparing a first ink solution having nanowire at a first diameter; b) preparing a second ink solution having nanowire at a second diameter; and c) depositing the first and second ink solutions onto a substrate sequentially to form a nanowire network.

It will be appreciated by those skilled in the art that the above discussion is for demonstration purpose; and the examples discussed above are some of many possible examples. Other variations are also applicable.

In a further aspect of the present invention, it is directed to a transparent conductive electrode having improved adhesion.

FIG. 1 is an illustration of an exemplary layer design in the prior art. The conductive electrode 100 comprises a substrate 102, a layer of nanowire film 104 situated on top of the substrate, and a layer of adhesion promoter deposited on top of the nanowire layer 106.

Comparing to the three-layer structure in the prior art, the transparent electrode with improved adhesion 120 is substantially a single layer structure. The electrode in the present invention 120 as in FIG. 16, comprises a single layer with one zone substantially of substrate (122), and another zone (124) having more nanowires than the zone of substrate (122). There is no interface between the zone of substrate (122) and the zoon of nanowires (124).

In one example of the present invention, the substrate 102 is a PET (Polyethylene terephthalates) and the zone of substrate 122 comprises substantially PET (Polyethylene terephthalates). The zone of nanowires 124 comprises a metal nanowire selected from the group of the metal nanowires made of copper, silver, gold, aluminum, nickel, lead, platinum or alloy of them.

The substantial single layer electrode 120 is made from a pseudo transitional structure 130. Referring to FIGS. 17a-c, first a substrate 120 is provided. Then a mixture comprising nanowires and a polymer is deposited on top of the substrate. After drying, a pseudo transitional structure shown as FIG. 17c is formed. Transitional structure 130 is further subject to temperature or pressure annealing to afford the electrode structure 120.

In one example of the present invention, the electrode is shown as in FIG. 16, comprising two zones 122 and 124.

In another example of the present invention, the electrode can also be a graded layer structure as shown as in FIG. 18, further comprising a zone having more nanowire in the substrate but less nanowire than the nanowire layer. The graded zone structure is designed to afford a more coherent structure, better adhesion and longer lifetime.

The graded electrode structure is made according to the flow diagram in FIGS. 19a-d. One additional deposition and drying step is added after the first deposition and drying, before the annealing step.

In still another embodiment of the present invention, a method of making of the electrode with improved adhesion is disclosed. The method comprises a surface functionalization step, functionalizing the substrate with desired functionalities to adhere to groups in the transparent conductive zone.

In still another embodiment of the present invention, a method of making of the electrode with improved adhesion is disclosed. The method comprises a deposition step laying down a mixture comprising nanowires and a thermo-sensitive polymer on top of the substrate, and a drying step forming a conductive film adhering to the substrate, and an annealing step, which heat the layer above glass transition temperature of polymer, followed by applying a temperature or pressure or both to remove the stress in the film and to embed the wire into the substrate surface.

In still another embodiment of the present invention, a method of making of the electrode with improved adhesion is disclosed. The method comprises a deposition step laying down a mixture comprising nanowires and a polymer on top of the substrate, and a drying step forming a conductive film adhering to the substrate, and a dry etching step (plasma etching) which etches away the surface polymer, followed by an annealing step, by applying a temperature or pressure or both to remove the stress in the film and to embed the wire into the substrate surface.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments. Furthermore, for ease of understanding, certain method procedures may have been delineated as separate procedures; however, these separately delineated procedures should not be construed as necessarily order dependent in their performance. That is, some procedures may be able to be performed in an alternative ordering, simultaneously, etc. In addition, exemplary diagrams illustrate various methods in accordance with embodiments of the present disclosure. Such exemplary method embodiments are described herein using and can be applied to corresponding apparatus embodiments, however, the method embodiments are not intended to be limited thereby.

Although few embodiments of the present invention have been illustrated and described, it would be appreciated by those skilled in the art that changes may be made in these embodiments without departing from the principles and spirit of the invention. The foregoing embodiments are therefore to be considered in all respects illustrative rather than limiting on the invention described herein. Scope of the invention is thus indicated by the appended claims rather than by the foregoing description, and all changes which come within the meaning and range of equivalency of the claims are intended to be embraced therein. As used in this disclosure, the term “preferably” is non-exclusive and means “preferably, but not limited to.” Terms in the claims should be given their broadest interpretation consistent with the general inventive concept as set forth in this description. For example, the terms “coupled” and “connect” (and derivations thereof) are used to connote both direct and indirect connections/couplings. As another example, “having” and “including”, derivatives thereof and similar transitional terms or phrases are used synonymously with “comprising” (i.e., all are considered “open ended” terms)—only the phrases “consisting of” and “consisting essentially of” should be considered as “close ended”. Claims are not intended to be interpreted under 112 sixth paragraph unless the phrase “means for” and an associated function appear in a claim and the claim fails to recite sufficient structure to perform such function.

We claim:

1. A transparent conductive electrode, comprising:
a substrate;
a transparent conductive layer, comprising
a network of metal nanowires having a first group of nanowire veins and a second group of nanowire veins, wherein the first and second group of nanowire veins are substantially different in diameters, wherein the first group of nanowire veins form the skeleton of the network and the second group of nanowire veins branch out from the first group of nanowire veins, join another nanowire vein to form a closed loop or a continuous branching system; and
a diffused conductive material formed in contact with the metal nanowire network and the conductive material wraps around and fills between the nanowire veins.

2. The electrode of claim 1, wherein the transparent conductive layer comprises free end veins, and the freely ending veins extend into the conductive materials.

3. The electrode of claim 1, wherein the thickness of the transparent conductive layer is 200 nm or less.

4. The electrode of claim 1, wherein the thickness of the diffused conductive material is 20 to 30 nm or less.

5. The electrode of claim 1, wherein the electrode has at least 80% light transmission in the wavelength ranges 400-1000 nm.

6. The electrode of claim 1 has a sheet resistance of 0.1 Ohm/m²-1000 Ohm/m².

7. The electrode of claim 1, wherein the diffused conductive material forms anisotropic layer for gathering charge from the junctions of the nanowires and/or delivering charge to the junctions of the nanowires.

8. The electrode of claim 7, wherein the isotropic layer has a sheet resistance of 10 Ohm/m2 to 1000 Ohm/m2.

9. The electrode of claim 1, wherein the substrate is a piece of glass.

10. The electrode of claim 1, wherein the substrate is a plastic film composed of polyethylene terephthalate (PET), polyethylene naphathalate (PEN), polycarbonate, polyimides, polyamids, polyetheretherketone (PEEK), polyethersulfone (PES), polyetherimide (PEI), polyethylene naphtalate (PEN), polyester (PET), polycarbonate (PC), and cyclo olefin polymer (COP) or copolymer (COC), polymethylmethacrylate (PMMA), or combinations or copolymers thereof.

11. The electrode of claim 10, wherein the substrate has one dimension larger than 0.05 m.

12. The electrode of claim 1, wherein the network of nanowires is deposited from a solution with no polymer binders.

13. The electrode of claim 1, wherein the metal nanowires are made of copper, silver, gold, aluminum, nickel, lead, platinum or alloy of them.

14. The electrode of claim 1, wherein the diffusive conductive materials are conductive or semiconducting metal oxides from fluorine doped tin oxide (FTO), indium tin oxide (ITO), aluminum doped zinc oxide (AZO), gallium doped zinc oxide (GZO), boron doped zinc oxide (BZO)

15. The electrode of claim 1, wherein the diffusive conductive material is a conductive polymer.

16. The electrode of claim 1, wherein the diameters of nanowires of the first group are from 100 nm to 500 nm.

17. The electrode of claim 1, wherein the first group of nanowires is randomly oriented.

18. The electrode of claim 1, wherein the first group of nanowires is regularly oriented.

19. The electrode of claim 1, wherein the maximum distance from any location in the transparent electrode to a nearest nanowire in the network in the range between 1 to 50 microns.

20. The electrode of claim 19, wherein the conductive material is a chemical compound of RI between 1.3-1.8.

21. A transparent conductive electrode, comprising:
a substrate;
a transparent conductive layer, comprising
a network of metal nanowires having a first group of nanowire veins and a second group of nanowire veins, wherein the first and second group of nanowire veins are substantially the same in diameters, wherein the first group of nanowire veins form the skeleton of the network and the second group of nanowire veins branch out from the first group of nanowire veins, join another nanowire vein to form a closed loop or a continuous branching system; and
wherein the diffused conductive material forms a continuous homogenous isotropic phase (layer), the metal nanowire network is embedded in the homogenous diffused conductive material phase (layer) and the diffused conductive material and metal nanowire network is substantially a single layer with one thickness.

22. The electrode of claim 21, wherein the thickness of the single layer of metal nanowire network and conductive material is equal to or less than 200 nm.

23. The method of forming a transparent electrode, comprising
a) preparing an ink solution that contains a first group of nanowires and a second group of nanowires;
b) functionalizing a substrate on the surface where the growth or anchoring of the first group of nanowires occur;
c) depositing the nanowire ink onto the surface of the substrate; and
d) curing the resulted film to let the first group of nanowires interact specifically with the surface of the substrate to form the skeleton of a nanowire network and land the second group of nanowires in between the first group of nanowires,
wherein the first and second group of nanowires differ in diameters.

24. The method of claim 23, wherein the ink solution comprises a group of surface-functionalized nanowires.

25. The method of claim 23, wherein the substrate is surface functionalized with dithiol, dicyanide, diisocyanate, dicarboxylate, or imidazole groups or a combination of them.

26. The method of claim 23, wherein the nanowires comprise at least one of copper, silver, gold, aluminum, nickel, lead, platinum or alloy of them.

27. A transparent conductive electrode having improved adhesion, comprising:
a substrate; and
a transparent conductive zone, comprising nanowires and adhesion promoter, wherein the adhesion promoter is a thermoplastic polymer and
there is no interface between the substrate and transparent conductive zone and there is no distinct interface between the adhesion promoter polymer layer and the conductive layer.

28. The electrode of claim 27, wherein the substrate is a thermoplastic polymer selected from polyethylene terephthalate (PET), polyethylene naphathalate (PEN), polycarbonate, and cyclo olefin polymer (COP) or copolymer (COC).

29. The electrode of claim 27, wherein the substrate is a PET and adhesion promoting polymer layer is a PET, or having the same composition as the surface composition of substrate.

30. The electrode of claim 27, wherein the conductive layer has metal nanowires embedded in the adhesion promoting layer.

31. The electrode of claim 27, wherein the metal nanowire is made of copper, silver, gold, aluminum, nickel, lead, platinum or alloy of them.

32. A method for making an electrode, comprising
making the electrode of claim 1, comprising
providing a substrate and cleaning its surface;
depositing first an adhesion promotion layer from polymer solution on the surface of the substrate;
depositing silver nanowire solution on the adhesion promotion layer to form conductive film on top; and
annealing the electrode at a temperature 5-15 degrees above the Tg of the adhesion promotion polymer layer.
